(19) United States
(12) Patent Application Publication
(10) Pub. No.: US 2007/0035012 A1
(43) Pub. Date: Feb. 15, 2007

(54) Integrated solder and heat spreader fabrication

(76) Inventors: Carl L. Deppisch, Chandler, AZ (US); Edward L. Martin, Chandler, AZ (US); Sabina J. Houle, Phoenix, AZ (US); James P. Mellody, Phoenix, AZ (US); Marvin J. Burgess, Naperville, IL (US); Maureen A. Brown, River Grove, IL (US); Robert C. DeBlieck, Cary, IL (US); David P. Carroll, Streamwood, IL (US)

Correspondence Address: BUCKLEY, MASCHOFF, TALWALKAR LLC, 50 LOCUSTAVENUE, NEW CANAAN, CT, 06840, US

(21) Appl. No.: 11/580,377

(22) Filed: Oct. 13, 2006

Related U.S. Application Data
(62) Division of application No. 10/729,623, filed on Dec. 5, 2003.

(51) Int. Cl. H01L 23/34

(52) U.S. Cl. 257/706; 257/718; 257/E23.026

(57) ABSTRACT

A system may include an integrated heat spreader that includes a portion of solder material and a thermal conductor, wherein a voidless interface exists between the solder material and a first side of the thermal conductor.

### BACKGROUND

An integrated circuit (IC) die includes a semiconductor substrate and various electronic devices integrated therewith. The electronic devices may generate heat during operation of the IC die. This heat may adversely affect the performance of the IC die, and in some cases may damage one or more of its integrated electronic devices.

Conventional systems use fans and/or temperature monitors to regulate the heat to which an IC die is subjected. Heat spreaders, heat sinks, and or heat pipes may also be used to direct heat away from an IC die.

### BRIEF DESCRIPTION OF THE DRAWINGS

FIG. 1 is a cross-sectional side view of an apparatus according to some embodiments.

FIG. 2 is a cross-sectional side view of an apparatus according to some embodiments.

FIG. 3 is a diagram of a process according to some embodiments.

FIG. 4 illustrates a method for fabricating an apparatus according to some embodiments.

FIG. 5A is a top view of a composite strip according to some embodiments.

FIG. 5B is a cross-sectional view of a composite strip according to some embodiments.

FIG. 5C is a cross-sectional view of a composite strip according to some embodiments.

FIG. 6 is a top view of a composite strip according to some embodiments.

FIG. 7 is a top view of an apparatus according to some embodiments.

FIG. 8 is a diagram of a process according to some embodiments.

FIG. 9 is a side view of a thermal conductor and a carrier during a process according to some embodiments.

FIG. 10A is a side view of a thermal conductor and a piece of solder material during a process according to some embodiments.

FIG. 10B is a side view of a thermal conductor and a piece of solder material during a process according to some embodiments.

FIGS. 11A through 11C comprise sequential side views of a thermal conductor and a piece of solder material during a process according to some embodiments.

FIGS. 12A through 12C comprise sequential side views of a thermal conductor and a piece of solder material during a process according to some embodiments.

FIG. 13 is a side view of an apparatus according to some embodiments.

FIG. 14 is a side view of a system according to some embodiments.

### DETAILED DESCRIPTION

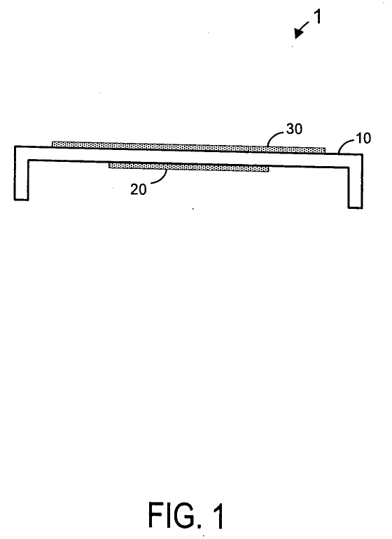

FIG. 1 is a cross-sectional side view of apparatus 1 according to some embodiments. Apparatus 1 comprises thermal conductor 10, solder material 20, and solder material 30. Apparatus 1 may be used to dissipate heat from an IC die according to some embodiments. Examples of such a use are discussed below.

As shown, thermal conductor 10 comprises an integrated heat spreader. Thermal conductor 10 may comprise any other structure for dissipating heat according to some embodiments, including but not limited to a heat pipe and a heat sink. Thermal conductor 10 may comprise any currently- or hereafter-known thermally conductive material. Non-exhaustive examples include copper and aluminum, which may or may not be plated with a different thermally-conductive material, including but not limited to nickel and gold. In some embodiments, thermal conductor 10 comprises nickel-plated copper that is in turn plated with gold, silver, tin, palladium, and/or another material.

Solder material 20 and solder material 30 may comprise any material usable to unite metal surfaces. In some embodiments, solder material 20 and solder material 30 are composed of elemental indium, an indium-based material, or a tin-based material. A thermal conductivity of the soft solder may approximately equal 30 W/mK, but embodiments are not limited to this value. Solder material 20 and solder material 30 may each have a uniform thickness between 003 in. and 0.020 in., but again embodiments are not limited thereto. The composition and/or thickness of solder material 20 may differ from the composition and/or thickness of solder material 30.

Solder material 20 is coupled to a first side of thermal conductor 10 and solder material 30 is coupled to a second side of thermal conductor 10. According to some embodiments, one or both of the interfaces between solder material 20 and conductor 10 and solder material 30 and conductor 10 are voidless. In comparison to other interfaces, a voidless interface may provide increased strength at the interface, increased heat transfer across the interface and/or increased resistance to the development and propagation of cracks at the interface.

A surface area of solder material 30 is greater than a surface area of solder material 20. Such an arrangement may facilitate the dispersal of heat from a surface to which solder material 20 is coupled to a larger surface to which solder material 30 is coupled.

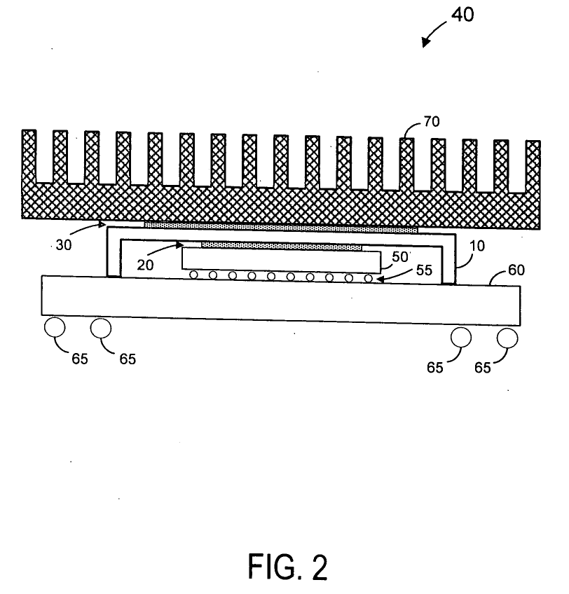

FIG. 2 is a cross-sectional side view of apparatus 40 including apparatus 1 according to some embodiments. Apparatus 40 includes IC die 50 coupled to solder material 20 of apparatus 10. IC die 50 includes integrated electrical devices and may be fabricated using any suitable material and fabrication techniques. IC die 50 may provide one or more functions. In some embodiments, IC die 50 comprises a microprocessor chip having a silicon substrate.

Electrical contacts 55 are coupled to IC die 50 and may comprise Controlled Collapse Chip Connect (C4) solder bumps. Electrical contacts 55 may be electrically coupled to the electrical devices that are integrated into IC die 50. The electrical devices may reside between a substrate of IC die 50 and electrical contacts 55 in a “flip-chip” arrangement. In some embodiments, such a substrate resides between the electrical devices and electrical contacts 55.

Electrical contacts 55 are also coupled to electrical contacts (not shown) of substrate 60. In some embodiments, die 50 is electrically coupled to substrate 60 via wirebonds in addition to or as an alternative to electrical contacts 55. Substrate 60 may comprise an IC package, a circuit board, or other substrate. Substrate 60 may therefore comprise any ceramic, organic, and/or other suitable material. Substrate 60 comprises solder balls 65 for carrying power and I/O signals between elements of apparatus 40 and external devices. For example, solder balls 65 may be mounted directly to a motherboard (not shown) or onto an interposer that is in turn mounted directly to a motherboard. Alternative interconnects such as through-hole pins may be used instead of solder balls 65 to mount apparatus 40 to a motherboard, a socket, or another substrate.

Solder material 30 is coupled to heat sink 70. As such, apparatus 1 may increase a thermal coupling between die 50 and heat sink 70. Heat sink 70 may comprise any currently- or hereafter-known passive or active heat sink. A thermally-conductive flux, paste or other material may be disposed between solder material 30 and heat sink 70, and/or between solder material 20 and die 50.

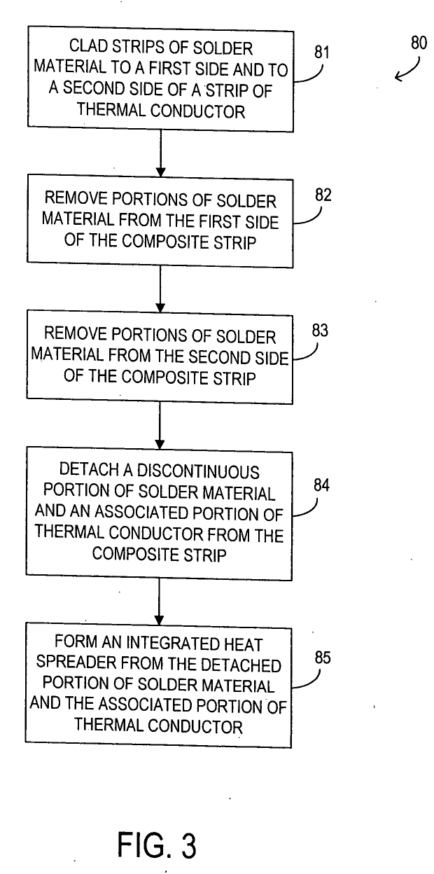

FIG. 3 is a diagram of process 80 according to some embodiments. Process 80 may be executed by one or more devices, and all or a part of process 80 may be executed manually. Process 80 may be executed by an entity different from an entity that manufactures apparatus 40, IC die 50 and/or IC substrate 60.

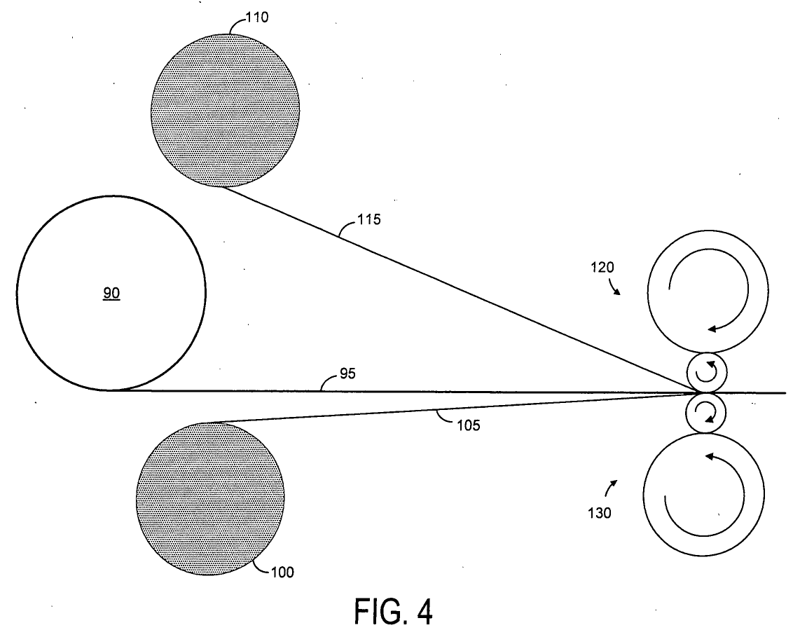

Initially, at 81, strips of solder material are clad to a first side and to a second side of a strip of thermal conductor. FIG. 4 illustrates an arrangement for cladding the material according to some embodiments. Drum 90 holds strip 95 in coil form, and drums 100 and 110 similarly hold strips 105 and 115, respectively. Strip 95 may comprise a strip of thermal conductor as described with respect to thermal conductor 10. Strip 105 and 115 may comprise solder material as described above with respect to solder material 20 and solder material 30.

Cladding may proceed by inserting strip 95, strip 105, and strip 115 into the junction of bonding rolls 120 and 130. Bonding rolls 120 and 130 are rotated in the direction of their associated arrows to highly compress the strips at the junction. The compression may drastically reduce the cross-sectional area of each strip, thereby creating a new metal surface on each strip that is bonded to a new metal of a facing strip without first exposing the new surfaces to the ambient atmosphere. Accordingly, upon exiting bonding rolls 120 and 130, voidless interfaces may exist between strip 115 and 95, and between strip 105 and 95.

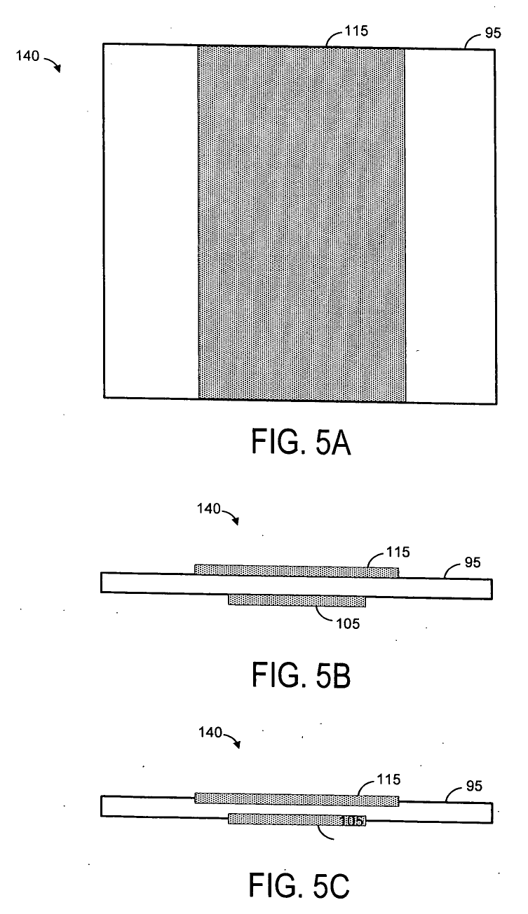

FIG. 5A is a top view of composite strip 140 as created according to some embodiments of process 80. Strip 115 is shown clad to a central portion of strip 95. FIG. 5B shows a cross-section of composite strip 140 in which strip 115 is clad to a central portion of a first surface of strip 95 and strip 105 is clad to a central portion of a second surface of strip 95. FIG. 5C shows a cross-section of composite strip 140 according to some embodiments. As shown, both strip 105 and strip 115 are slightly inlaid to strip 95.

Returning to process 80, portions of solder material are removed from a first side of composite strip 140 at 82. A skiving tool is used in some embodiments to dig a transverse trough across portions of a first side of composite strip 140. Portions of strip 95 might or might not be removed during 82. In some embodiments, some solder material might exist in the portions of the first side of composite strip 140 after 82.

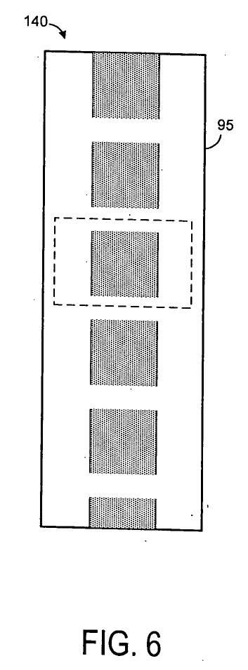

FIG. 6 shows a first side of composite strip 140 after 82. Portions of solder material are then removed from a second side of composite strip 140 at 83. The solder material may be removed from portions of the second side that correspond to the portions of the first side from which solder material is removed at 82. The portions of solder material may be removed from the first side and the second side of composite strip 140 simultaneously.

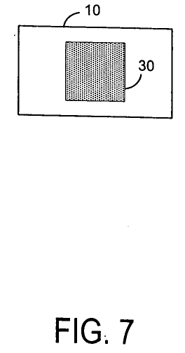

Next, at 84, a discontinuous portion of solder material and an associated portion of thermal conductor are detached from the composite strip. A dashed line in FIG. 6 shows portions of solder material and thermal conductor that may be detached from composite strip 140 at 84. The portions may be detached by stamping, cutting, or any other suitable system. FIG. 7 shows a top view of the detached portions according to some embodiments. The detached portions may comprise thermal conductor 10 and solder material 30 of FIG. 1. The detached portions may also comprise solder material 20, which is not shown in the view of FIG. 7.

An integrated heat spreader may be formed from the detached portions at 85. The integrated heat spreader may be formed by stamping thermal conductor 10 or by bending opposite ends of thermal conductor 10 to achieve the shape shown in FIG. 1.

The integrated heat spreader may be assembled into an apparatus such as apparatus 40. According to some embodiments, solder material 20 and solder material 30 are reflowed at appropriate times during the assembly to bond to IC die 50 and heat sink 70, respectively. A temperature and/or pressure required to reflow solder material 20 may differ from a temperature and/or pressure required to reflow solder material 30, thereby enabling reflow of each material at different stages of assembly.

According to some embodiments, solder material is present only on one side of the composite strip. Therefore, only one of drums 100 and 110 are used at 81 and flow may proceed from 82 directly to 84. Embodiments of process 80 may result in a voidless interface between solder material and a thermal conductor.

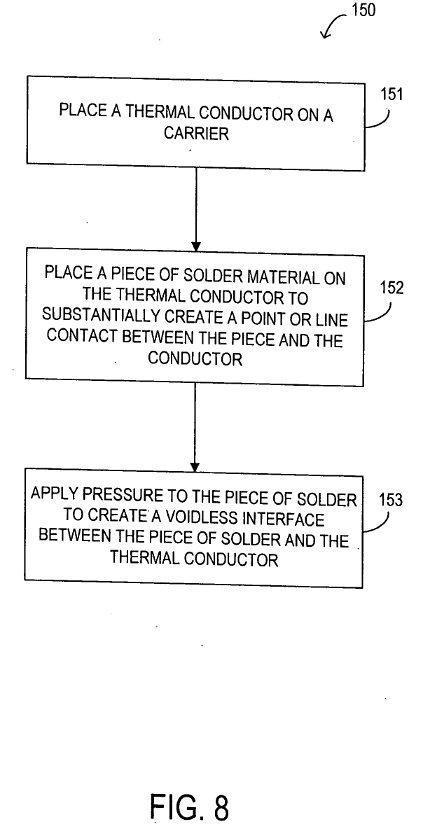

FIG. 8 is a diagram of process 150 according to some embodiments. Process 150 may be executed by one or more devices, and all or a part of process 150 may be executed manually. Process 150 may be executed by an entity different from an entity that manufactures apparatus 40, IC die 50, and/or IC substrate 60.

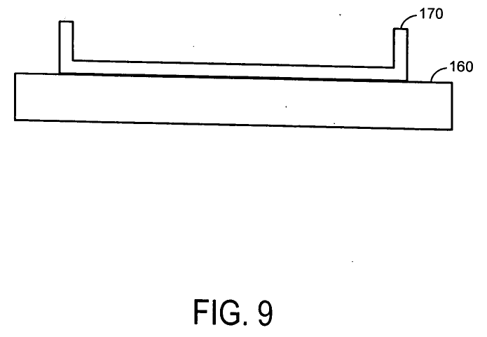

A thermal conductor is placed on a carrier at 151. FIG. 9 shows carrier 160 upon which thermal conductor 170 is placed at 151. Carrier 160 may comprise any base upon which process 150 may proceed. Carrier 160 may comprise an element of a single device that executes process 150.

Thermal conductor 170 may comprise any material described above with respect to thermal conductor 10, and/or any other suitable material. In some embodiments, thermal conductor 170 comprises copper. As shown in FIG. 9, thermal conductor 170 may be formed in the shape of a suitable integrated heat spreader prior to 151.

A piece of solder material is placed on the thermal conductor at 152 so as to substantially create a point or line contact between the piece of solder material and the thermal conductor. Such a point or line contact may be of any size that results in a voidless interface between the solder material and the thermal conductor as described below.

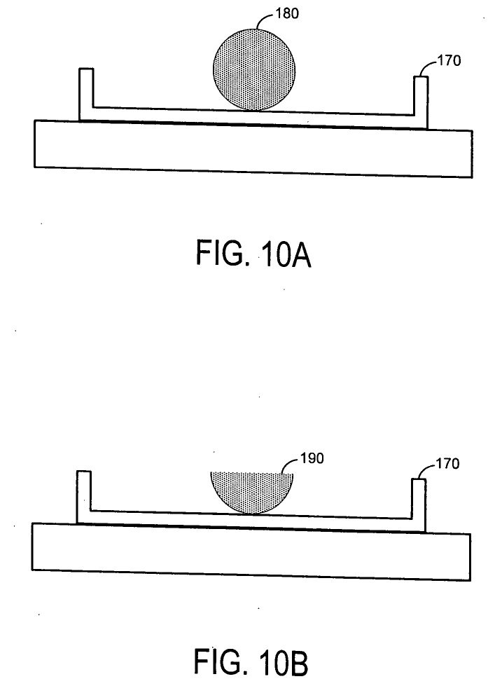

FIGS. 10A and 10B illustrate two embodiments of 152. Particularly, FIG. 10A shows substantially spherical piece of solder material 180, and FIG. 10B shows substantially hemispherical piece of solder material 190. The piece of solder material may possess many other geometries, such as a cylinder or other polygon, in order to substantially create a point or line contact between the piece and the thermal conductor. Some of these other geometries may require supporting elements to hold the piece on the thermal conductor in a manner that substantially creates a point contact. The piece of solder material placed on the thermal conductor may comprise any suitable solder material, including but not limited to indium or tin-based solder materials.

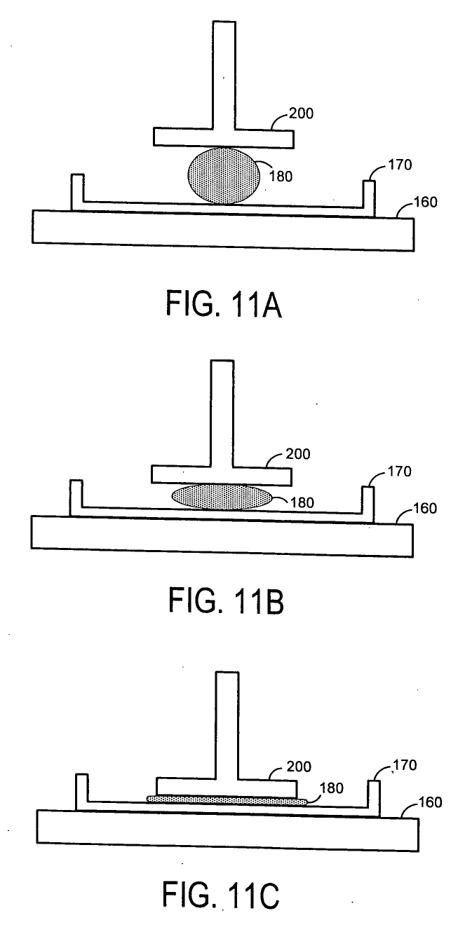

At 153, pressure and/or heat is applied to the piece of solder to create a voidless interface between the piece of solder and the thermal conductor. FIGS. 11A through 11C illustrate some embodiments of 153 using spherical piece of solder material 180. As shown, stamp 200 presses piece 180 against thermal conductor 170 while carrier 160 resists the pressure. Piece 180 is therefore compressed against conductor 170. Stamp 200 and carrier 160 may be elements of a single device.

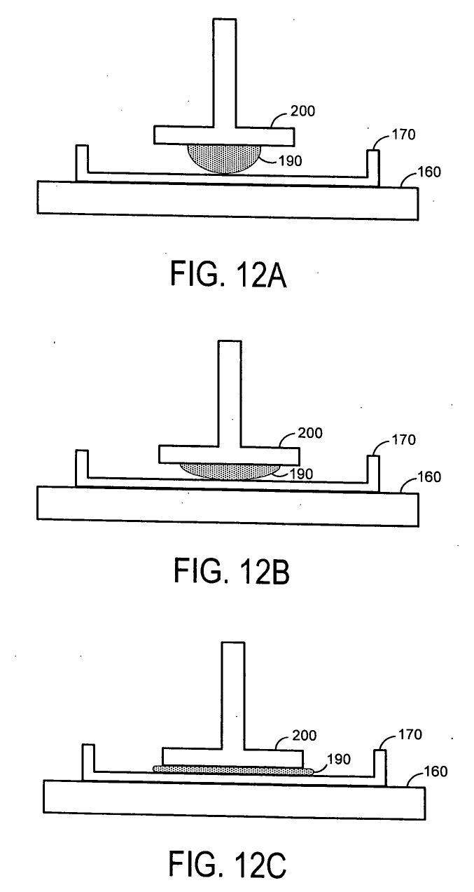

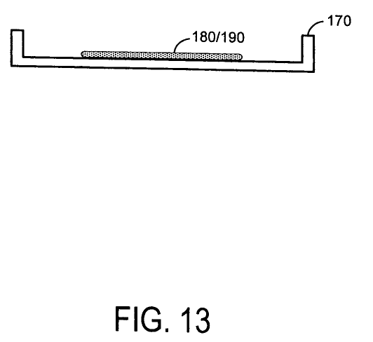

FIGS. 12A through 12C illustrate some embodiments of 153 using hemispherical piece of solder material 190. Stamp 200 is shown compressing piece 190 against thermal conductor 170 until piece 190 is of somewhat uniform thickness. FIG. 13 shows thermal conductor 170 after process 150. In either of the illustrated cases, the compression of the piece of solder material may drastically reduce its cross-sectional area so as to break up surface oxides and create new metal surfaces that are bonded to thermal conductor 170 without exposure to the ambient atmosphere. Accordingly, a voidless interface exists between the piece of solder material and thermal conductor 170 after process 150.

Thermal conductor 170 of FIG. 13 may be used in apparatus 40 of FIG. 2. Solder paste or other bonding material may be applied to a side of thermal conductor 170 that is opposite to the side on which the solder material is bonded in FIG. 13. Heat sink 70 may be bonded to the opposite side using the solder flux, paste or other bonding material. In some embodiments, solder material is bonded to the opposite side of thermal conductor 170 using process 80 or 150 prior to or after process 150 as described above.

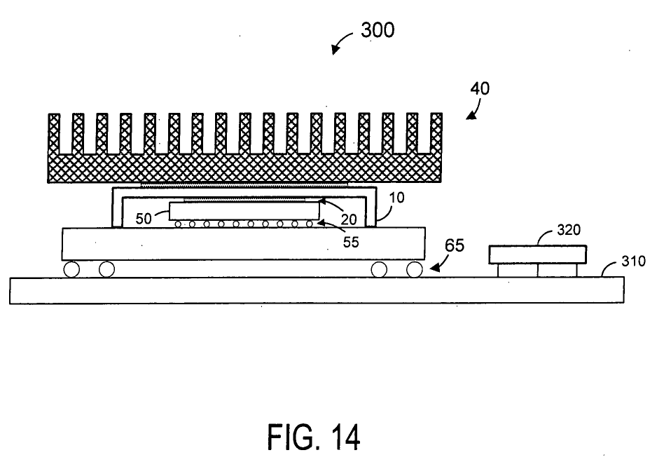

FIG. 14 illustrates a system according to some embodiments. System 300 includes apparatus 40 of FIG. 2, motherboard 310, and memory 320. IC die 50 of system 300 may comprise a microprocessor.

Motherboard 310 may electrically couple memory 320 to IC die 50. More particularly, motherboard 310 may comprise a memory bus (not shown) that is electrically coupled to solder balls 65 and to memory 320. Memory 320 may comprise any type of memory for storing data, such as a Single Data Rate Random Access Memory, a Double Data Rate Random Access Memory, or a Programmable Read Only Memory.

The several embodiments described herein are solely for the purpose of illustration. Some embodiments may include any currently or hereafter-known versions of the elements described herein. Therefore, persons skilled in the art will recognize from this description that other embodiments may be practiced with various modifications and alterations.

1.-10. (canceled)

11. A method comprising:
removing portions of solder material from a first side of a composite strip, the composite strip comprising a strip of solder material clad to the first side of a strip of thermal conductor,
wherein removing the portions of solder material leaves a plurality of discontinuous portions of solder material clad to the first side of the strip of thermal conductor.

12. A method according to claim 11, further comprising
removing second portions of solder material from a second side of the composite strip, the composite strip comprising a second strip of solder material clad to the second side of the strip of thermal conductor,
wherein removing the second portions of solder material leaves a plurality of discontinuous portions of solder material clad to the second side of the strip of thermal conductor.

13. A method according to claim 11, further comprising:
cladding the strip of solder material to the first side of the strip of thermal conductor.

14. A method according to claim 11, wherein one of the plurality of discontinuous portions of solder material is associated with a portion of the strip of thermal conductor, and further comprising:
detaching the one of the plurality of discontinuous portions of solder material and the associated portion of the strip of thermal conductor from the composite strip.

15. A method according to claim 14, further comprising:
forming an integrated heat spreader from the one of the plurality of discontinuous portions of solder material and the associated portion of the strip of thermal conductor.

16. A method comprising:
placing a piece of solder material on a thermal conductor to substantially create a point or line contact between the piece of solder material and the thermal conductor;
applying pressure to the piece of solder material to create a voidless interface between the piece of solder material and the thermal conductor.

17. A method according to claim 16, wherein the piece of solder material substantially comprises a sphere.

18. A method according to claim 16, wherein the piece of solder material substantially comprises a hemisphere.

19. A method according to claim 16, wherein the piece of solder material substantially comprises a cylinder.

20.-23. (canceled)
